(19) United States
(12) Patent Application Publication
(10) Pub. No.: US 2005/0219819 A1
(43) Pub. Date: Oct. 6, 2005

(54) Methods to improve heat exchanger performance in liquid cooling loops

(76) Inventors: Himanshu Pokharna, San Jose, CA (US); Eric DiStefano, Livermore, CA (US); Rajiv K. Mongia, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/816,025

(22) Filed: Mar. 31, 2004

(51) Int. Cl. H05K 7/20

(52) U.S. Cl. 361/700

(57) ABSTRACT

A thermal management system of a notebook computer that has an improved heat exchanger is described. Specifically, the heat exchanger may comprise a heat exchanger tube insert, a plurality of internal fins in the heat exchanger tube, or a flattened heat exchanger tube.

### FIELD OF THE INVENTION

The present invention pertains to the field of computer system design. More particularly, the present invention relates to methods to improve heat exchanger performance in computer cooling systems.

### BACKGROUND OF THE INVENTION

A computer system typically comprises a plurality of electronic components. Such components may include a central processing unit (CPU), a chipset, and a memory. During operation, the components dissipate heat. In addition, voltage stepping inside the computing system also generates heat. If the CPU, or any other electronic component, becomes overheated, performance may suffer and the component's life may be depreciated.

A thermal management system is typically used to remove heat from a computer system. One example of a thermal management system is a single-phase loop. In a single-phase loop, a liquid is used to absorb and remove heat from a component of a computer system. The liquid is then circulated to an area of the system where the heat is purged through natural convection.

A second example of a thermal management system is a refrigeration loop. A refrigeration loop typically uses a working fluid such as Freon to cool a component of a system. An evaporator or cold plate picks up heat from the component. The heat causes the working fluid to change phase from a liquid to a mixture of liquid and vapor or pure vapor. A pump, working as a compressor, then transports the working fluid to a heat exchanger. The compressor compresses or increases the pressure of the gas, which results in increase in temperature of the fluid. The heat exchanger is typically coupled to a fan that rejects the heat from the working fluid to the ambient air, turning the working fluid back into a liquid. The liquid, however, is still at a high pressure. An expansion valve reduces the pressure of the working fluid and returns the working fluid to the evaporator to complete the loop.

A third example of a thermal management system is a two-phase cooling loop. Like a refrigeration loop, a two-phase cooling loop also uses a pump to circulate a working fluid to cool a component of a system. A two-phase loop typically uses a working fluid such as water. An evaporator picks up heat from the component. Within the evaporator, the heat causes the working fluid to form a vapor. The working fluid is output from the evaporator to a heat exchanger, condenser, or heat sink. The heat exchanger is typically coupled to a fan that rejects the heat from the working fluid to the ambient air. The vapor condenses in the heat exchanger, converting the working fluid back to liquid. A pump is used to drive the working fluid to the evaporator to complete the loop. The fundamental difference between the refrigeration loop and the two-phase loop is that the heat exchanger in the refrigeration loop typically has a higher temperature than the heat exchanger in the two-phase loop.

### BRIEF DESCRIPTION OF THE DRAWINGS

FIG. 1A is a side view of a prior art heat exchanger;

FIG. 1B is a front view of a prior art heat exchanger;

FIG. 2 is an embodiment of a helical insert to decrease the temperature gradient in a heat exchanger tube;

FIG. 3 is an embodiment of the front view of a heat exchanger tube having internal fins;

FIG. 4 is an embodiment of the front view of a flattened heat exchanger tube;

FIG. 5 is an embodiment of a refrigeration loop comprising an improved heat exchanger tube that provides an enhanced temperature distribution; and

FIG. 6 is an embodiment of a two-phase loop comprising an improved heat exchanger tube that provides an enhanced temperature distribution.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

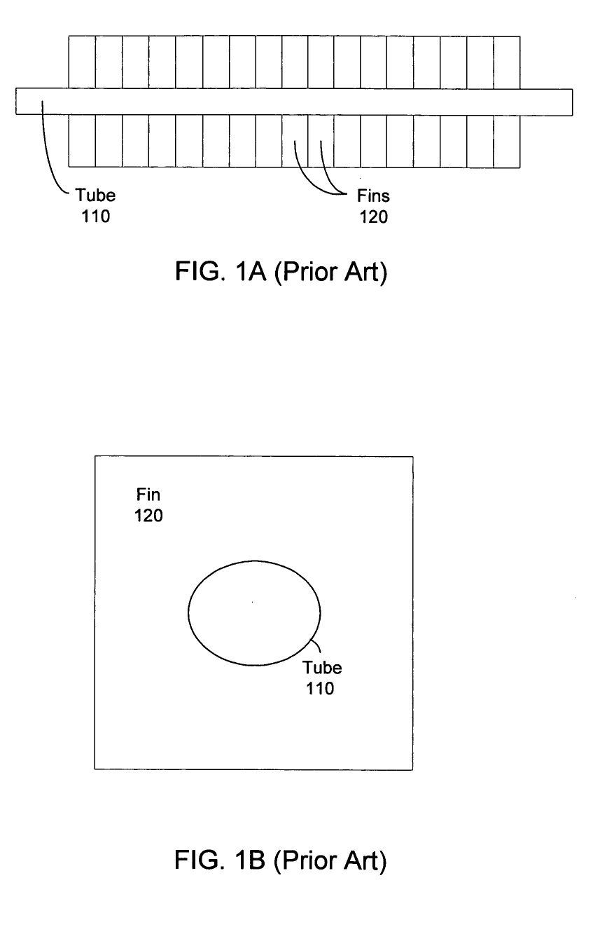

A computer system generally includes a heat sink to remove heat generated by the computer system. This heat sink typically consists of a heat exchanger coupled to a fan. FIG. 1A depicts the side view of a heat exchanger. The heat exchanger in FIG. 1A comprises a tube 110 coupled to a plurality of fins 120. A working fluid is transported inside the tube 110. The fins 120 help to remove the heat from the working fluid. The working fluid may comprise water, liquid metal, a mixture of alcohol and water, Freon, supercritical carbon dioxide, or any other refrigerant.

The front view of the heat exchanger is depicted in FIG. 1B. The tube 110 is cylindrical in shape and comprises circular openings on each end. The working fluid enters one end of the tube 110 and exits through the opposite end. However, the working fluid in a thermal management system is often comprised of a low conductivity liquid. As a result of the laminar nature of the flow of the working fluid through the tube 110, the working fluid inside the tube 110 may have a temperature gradient. Specifically, the center of the tube 110 may contain working fluid that is warmer than the region closer to the fins 120. Thus, the fins 120 remain at a temperature cooler than otherwise possible. A higher temperature at the fins 120 is desirable because it enables greater heat dissipation from the heat exchanger.

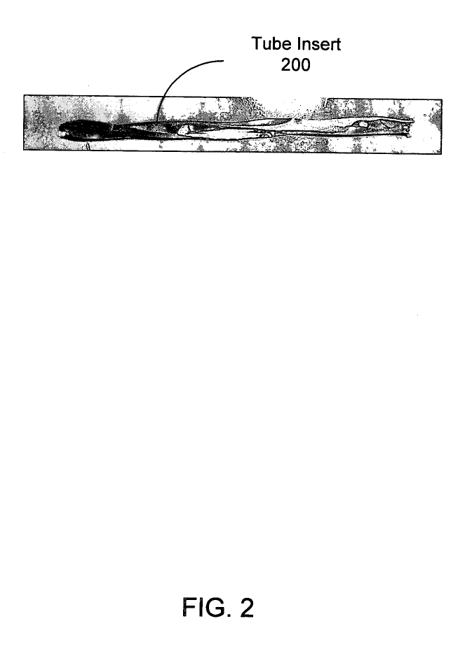

For one embodiment of the invention, a tube filling or insert is used to provide a more uniform temperature distribution of working fluid within a heat exchanger tube. The tube insert may be helically shape. A helical tube insert 200 is depicted in FIG. 2. The tube insert 200 may be a twisted tape. However, the heat exchanger tube insert is not limited to a helical shape. The diameter of the tube insert 200 may be less than or equal to the diameter of the tube. The heat exchanger tube may have a diameter that ranges from four-to six millimeters. The tube insert 200 may be closely fitted inside the tube to prevent the tube insert 200 from shifting inside the tube as working fluid flows through the tube.

The tube insert 200 enhances heat transfer by introducing a swirling motion in the flow of the working fluid. The resulting turbulence may enhance the mixture of the working fluid and the heat transfer coefficient for the fluid. A heat exchanger tube having a tube insert may be used in a single-phase loop, a two-phase loop, or a refrigeration loop.

The tube insert 200 may be inserted into the tube 110 manually or in an automated machine process. The tube insert 200 may be inserted into the tube 110 before or after the fins 120 are attached to the tube 110. The fins 120 may be attached to the exterior of the tube 110 by solder, epoxy, or press fit. The tube insert 200 may be manufactured using plastic, copper, aluminum, or another metal.

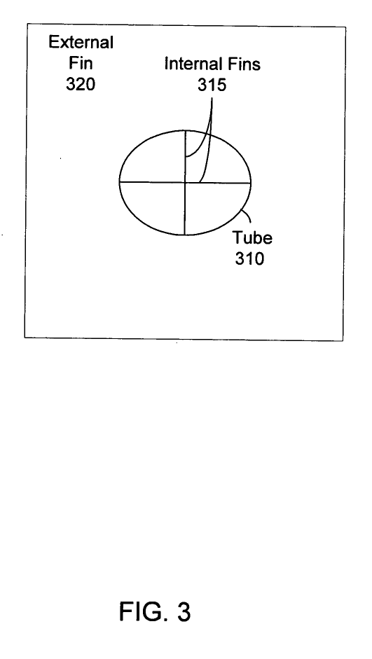

For another embodiment of the invention, internal fins are built into a heat exchanger tube to provide a more uniform temperature distribution of working fluid within the tube. FIG. 3 depicts the front view of a heat exchanger having a tube 310, internal fins 315, and external fin 320. The heat exchanger depicted in FIG. 3 has four internal fins. However, the tube is not limited to four internal fins. The heat exchanger tube may have one or more fins. The fins 315 in the tube may be manufactured at the same time as the heat exchanger tube 310. Thus, the internal fins 315 may comprise the same material as the heat exchanger tube. For example, the tube and the fins inside of the tube may be manufactured with copper. After the tube and the internal fins are manufactured, additional external fins 320 may be attached to the exterior of the tube using solder, epoxy, or press fit. As with tube inserts, the heat exchanger tube having internal fins may be used as part of a single-phase loop, two-phase loop, or a refrigeration loop.

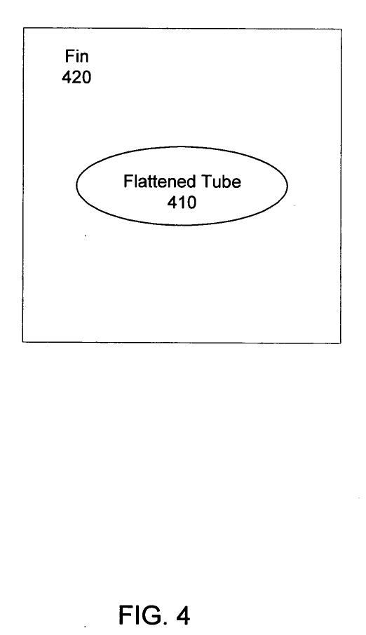

For yet another embodiment of the invention, a flattened tube may be used to provide a more uniform temperature distribution of working fluid within the heat exchanger tube. FIG. 4 depicts the front view of a flattened heat exchanger tube. The heat exchanger of FIG. 4 comprises a flattened tube 410 and external fins 420. By flattening the tube inside of a heat exchanger, the distance from the center to the edge of the tube is reduced.

For one embodiment of the invention, the distance from the top of the tube to the bottom of the tube 410 is approximately two millimeters. By limiting the distance between the top of the tube and the bottom of the tube, the temperature of the working fluid inside the tube is kept more uniform. As a result, heat conduction from the core is improved. The distance from the left side of the tube to the right side of the tube may be approximately eight millimeters.

For another embodiment of the invention, rather than being flattened from top to bottom as depicted in FIG. 4, the tube may be flattened from side to side. Thus, the tube may be approximately two millimeters from the left side of the tube to the left side of the tube. The tube may measure approximately eight millimeters from the top of the tube to the bottom of the tube.

The tube 410 may be flattened after the tube 410 is manufactured. The tube 410 may be flattened with a machine press. Fins 420 may then be attached to the flattened tube 410 using solder, epoxy, or press fit. The flattened tube 410 may be used in a heat exchanger that is a part of a single-phase loop, two-phase loop, or refrigeration loop.

For yet another embodiment of the invention, a tube insert may be used with a flattened heat exchanger tube. The tube insert should closely fit inside of the flattened tube. The tube insert may be a helically shaped to introduce swirl, enhance mixing, and decrease the heat transfer coefficient to the working fluid.

For yet another embodiment of the invention, a plurality of fins may be manufactured inside of a flattened tube. For this embodiment of the invention, the heat exchanger tube may be manufactured in a flattened shape. The internal fins may be manufactured at the same time. The flattened tube having internal fins may promote a uniform temperature inside the heat exchanger tube.

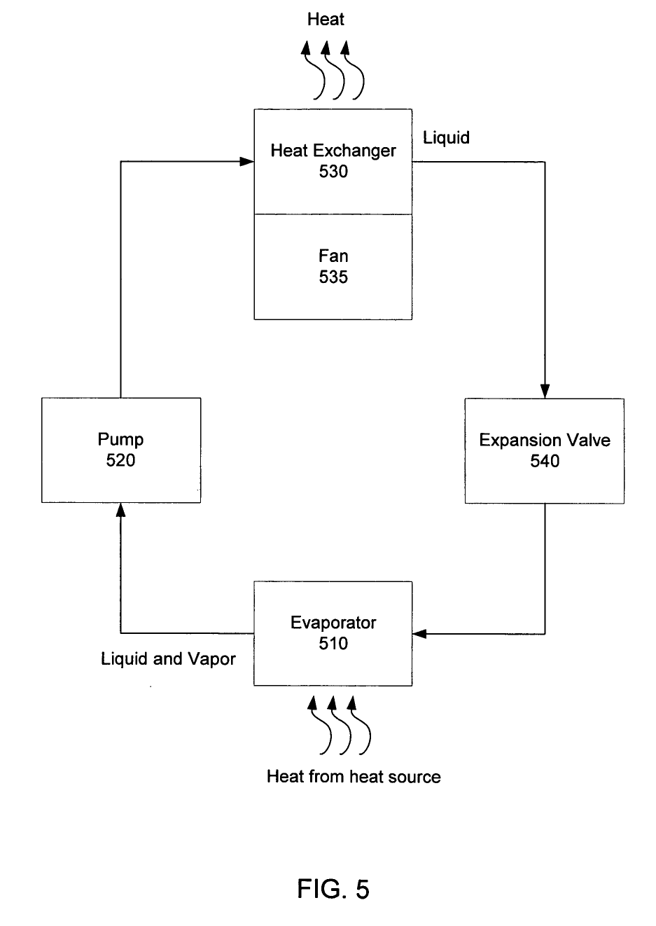

FIG. 5 depicts an embodiment of a refrigeration loop comprising a heat exchanger that provides improved temperature distribution. The refrigeration loop may be part of a thermal management system in a computer. The computer may be a server, a desktop, or a notebook computer. A cold plate or an evaporator 510 picks up heat from a heat source. The heat source may be a processor or another component of the computer system. The heat causes the working fluid to change phase from a liquid to a mixture of liquid and vapor or pure vapor. A pump 520 transports the working fluid to a heat exchanger 530. The heat exchanger 530 may comprise a helical tube insert. The heat exchanger 530 is coupled to a fan 535 that rejects the heat from the working fluid to the ambient air, turning the working fluid back into a liquid. The liquid, however, is still at a high pressure. An expansion valve 540 reduces the pressure of the working fluid and returns the working fluid to the evaporator 510 to complete the loop.

For another embodiment of the invention, the heat exchanger 530 may comprise a heat exchange tube having a plurality of fins inside of the tube. For yet another embodiment of the invention, the heat exchanger 530 may comprise a flattened heat exchanger tube.

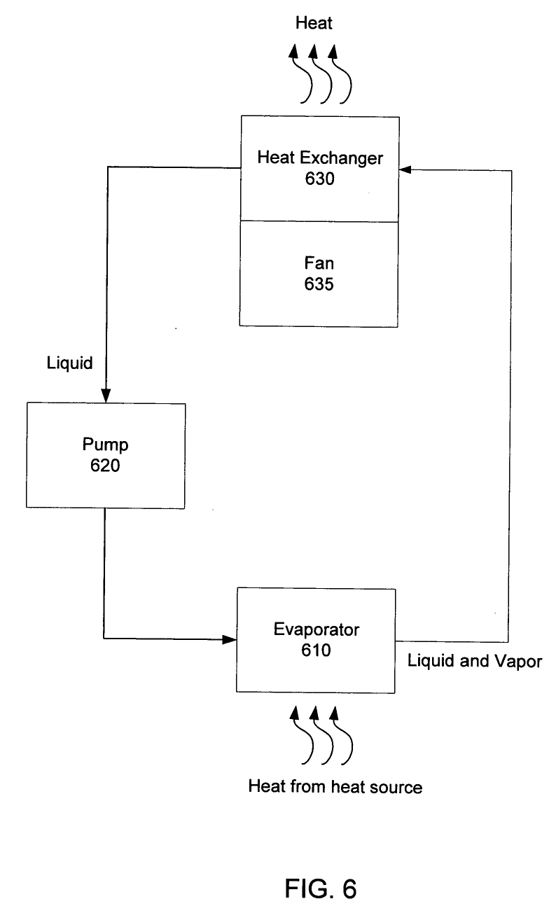

FIG. 6 depicts an embodiment of a two-phase loop in a thermal management system of a notebook computer. The two-phase loop comprises a heat exchanger that provides improved temperature distribution. An evaporator 610 picks up heat from a computer component. Within the evaporator 610, the heat causes the working fluid to form a vapor. The working fluid is output from the evaporator 610 to a heat exchanger 630. The heat exchanger 630 may comprise a flattened heat exchanger tube that limits the distance between the top of the tube and the bottom of the tube to approximately two millimeters. The distance from the left side of the tube to the right side of the tube is approximately eight millimeters.

The heat exchanger 630 is coupled to a fan 635 that rejects the heat from the working fluid to the ambient air. The vapor condenses in the heat exchanger 630, converting the working fluid back to liquid. A pump 620 is used to drive the working fluid to the evaporator 610 to complete the loop.

For another embodiment of the invention, the heat exchanger tube may comprise a tube insert for introducing a swirling motion in the flow of the working fluid. For yet another embodiment of invention, the heat exchanger tube comprises internal fins to make a more uniform temperature profile within the tube.

In the foregoing specification the invention has been described with reference to specific exemplary embodiments thereof. It will, however, be evident that various modification and changes may be made thereto without departure from the broader spirit and scope of the invention as set forth in the appended claims. The specification and drawings are, accordingly, to be regarded in an illustrative rather than restrictive sense.

1. A mobile computing device, comprising:
a processor;
an evaporator thermally coupled to the processor, wherein a working fluid of the evaporator picks up heat generated by the processor; and
a heat exchanger coupled to the evaporator to remove heat from the mobile computing device, wherein the heat exchanger comprises a flattened tube and a plurality of fins coupled to the outside of the tube.

2. The mobile computing device of claim 1, wherein the flattened evaporator tube is approximately two millimeters from top to bottom and eight millimeters from side to side.

3. The mobile computing device of claim 1, further comprising a fan coupled to the heat exchanger to reject the heat from the working fluid in the heat exchanger.

4. The mobile computing device of claim 1, wherein the flattened tube comprises internal fins.

5. The mobile computing device of claim 1, wherein the flattened tube comprises a tube insert.

6. The mobile computing device of claim 5, wherein the tube insert is helically shaped.

7. The mobile computing device of claim 1, wherein the working fluid is water.

8. A method, comprising:
manufacturing a heat exchanger tube for a computer system;
adding a tube filling into the heat exchanger tube; and
attaching a plurality of fins to the exterior of the heat exchanger tube.

9. The method of claim 8, wherein the tube filling is a twisted tape.

10. The method of claim 8, wherein the tube filling is helically shaped.

11. The method of claim 10, wherein the helically shaped tube filling comprises copper.

12. The method of claim 8, wherein the plurality of fins is attached to the heat exchanger tube by solder.

13. The method of claim 8, wherein the plurality of fins is attached to the heat exchanger by epoxy.

14. The method of claim 8, wherein the plurality of fins is attached to the heat exchanger by press fit.

15. A thermal management system of a computer system, comprising:
a heat generating component;
a cold plate coupled to the component to remove heat from the component, wherein the heat is transported via a working fluid; and
a pump coupled to the cold plate to transport the working fluid from the cold plate to a heat exchanger, wherein the heat exchanger comprises a tube filling that closely fits the tube.

16. The thermal management system of claim 15, wherein the tube filling has a diameter that is less than or equal to the tube diameter.

17. The thermal management system of claim 16, wherein the heat exchanger tube is approximately five millimeters in diameter.

18. The thermal management system of claim 15, wherein the tube filling comprises plastic.

19. The thermal management system of claim 15, wherein the tube filling comprises aluminum.

20. The thermal management system of claim 15, wherein the tube filling is helically shaped.

21. A thermal management system, comprising:
means for providing a uniform temperature distribution of working fluid within a heat exchanger tube; and
means for removing heat from a computer system.

22. The thermal management system of claim 21, further comprising:
means for reducing the distance from the top of the heat exchanger tube to the bottom of the heat exchanger tube.

23. A heat exchanger, comprising:
a tube having n internal fins to provide an even temperature distribution to the working fluid inside of the tube, wherein n is an integer greater than or equal to one; and
a plurality of fins coupled to the outside of the tube to help remove heat from the tube.

24. The heat exchanger of claim 23, wherein the n internal fins are built into the the tube.

25. The heat exchanger of claim 23, wherein the heat exchanger is part of a single-phase loop.

26. The heat exchanger of claim 23, wherein the heat exchanger is part of a refrigeration loop.

27. The heat exchanger of claim 23, wherein the heat exchanger is part of a two-phase loop.

28. The heat exchanger of claim 23, wherein the tube is four to six millimeters in diameter.

29. The heat exchanger of claim 23, wherein the tube and the internal fins comprise copper.
